(19) United States
(12) Patent Application Publication
(10) Pub. No.: US 2013/0256779 A1
(43) Pub. Date: Oct. 3, 2013

(54) METHOD OF MANUFACTURING SEMICONDUCTOR DEVICE AND SEMICONDUCTOR DEVICE

(71) Applicant: KABUSHIKI KAISHA TOSHIBA, Tokyo (JP)

(72) Inventors: Keiichi SAWA, Mie-ken (JP); Tetsuya Kai, Kanagawa-ken (JP); Shinji Mori, Kanagawa-ken (JP); Kenichiro Toratani, Kanagawa-ken (JP); Masayuki Tanaka, Mie-Ken (JP)

(73) Assignee: Kabushiki Kaisha Toshiba, Tokyo (JP)

(21) Appl. No.: 13/804,104

(22) Filed: Mar. 14, 2013

(30) Foreign Application Priority Data
Mar. 30, 2012 (JP) 2012-82864

(51) Int. Cl. H01L 29/40; H01L 29/423

(52) U.S. Cl. CPC H01L 29/401; H01L 29/42364
USPC 257/321; 438/594

(57) ABSTRACT

A method of manufacturing a semiconductor device comprising: forming a first insulating film on a semiconductor substrate; forming an adsorption film on the first insulating film; forming a first film containing germanium on the adsorption film; forming a second insulating film on the first film; forming a floating electrode film on the second insulating film; forming a third insulating film on the floating electrode film; and forming a gate electrode on the third insulating film.

### CROSS-REFERENCE TO RELATED APPLICATION

This application is based upon and claims the benefit of priority from the prior Japanese Patent Application No. 2012-82864, filed Mar. 30, 2012, the entire contents of which are incorporated herein by reference.

### FIELD

Embodiments described herein relate to a method of manufacturing a semiconductor device and to a semiconductor device.

### BACKGROUND

For example, in a charge-storage-type non-volatile semiconductor memory device such as a NAND flash memory, writing or erasing is performed by controlling potentials of control gates. In the charge-storage-type non-volatile semiconductor memory device, a high voltage is required to perform writing or erasing. However, when the high voltage is applied to a cell, a high electric field may also be applied to adjacent cells and erroneous writing or erroneous erasing may occur in the adjacent cells. Accordingly, there is a need to improve charge injection efficiency of a tunnel insulating film and reduce a writing voltage and an erasing voltage.

### DESCRIPTION OF THE DRAWINGS

FIG. 1A is a cross-sectional view showing a cross-sectional structure of a semiconductor device 1a of a first embodiment which is taken in a direction perpendicular to a word line thereof;

FIG. 1B is a cross-sectional view showing a cross-sectional structure of the semiconductor device 1a of the first embodiment which is taken in a direction perpendicular to a bit line thereof;

FIG. 2 is an enlarged cross-sectional view showing a structure of a tunnel insulating film 11a in FIGS. 1A and 1B;

FIGS. 3A to 3H are cross-sectional views showing cross sections in respective manufacturing processes of the semiconductor device 1a of the first embodiment viewed in a bit line direction;

FIG. 3I is a cross-sectional view showing a cross section in a certain manufacturing process of the semiconductor device 1a of the first embodiment viewed in a word line direction;

FIG. 4 is an enlarged cross-sectional view showing a structure of a tunnel insulating film 11b in a semiconductor device 1b of a comparative example;

FIG. 5A is an energy band diagram of a conduction band in the tunnel insulating film 11b of the semiconductor device 1b of the comparative example;

FIG. 5B is an energy band diagram of a conduction band in the tunnel insulating film 11b of the semiconductor device 1b of the comparative example during writing operation (during injection of electrons);

FIG. 6A is an energy band diagram of a conduction band in the tunnel insulating film 11a of the semiconductor device 1a of the first embodiment;

FIG. 6B is an energy band diagram of a conduction band in the tunnel insulating film 11a of the semiconductor device 1a of the first embodiment during writing operation (during injection of electrons);

FIG. 7 is a graph showing relationships between a tunnel current and an applied electric field in the first embodiment and the comparative example; and

FIG. 8 is a cross-sectional view showing a cross section of a semiconductor device 1c of a second embodiment viewed in a word line direction thereof.

### DETAILED DESCRIPTION

Embodiments of the present invention are described below with reference to the drawings. In the description, the same portions are denoted by the same reference numerals throughout the drawings. Moreover, dimensional ratios in the drawings are not limited only to the illustrated ratios. Note that the embodiments do not limit the present invention.

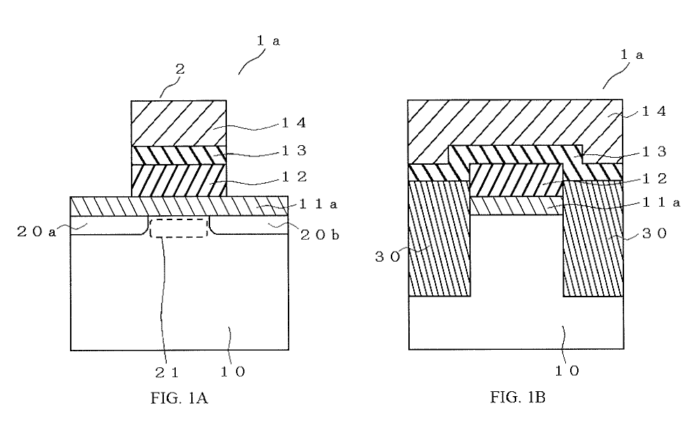

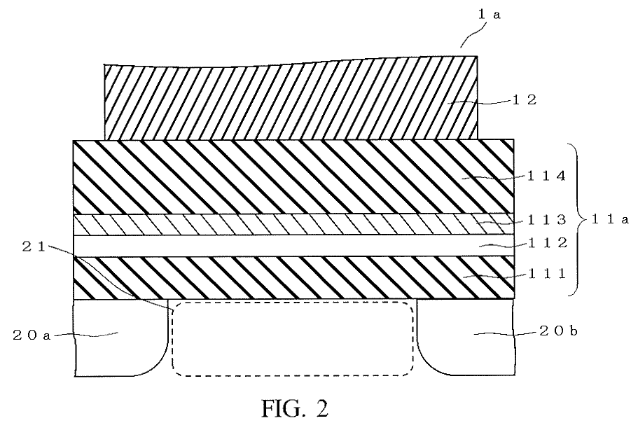

A structure of a semiconductor device 1a of a first embodiment is described with reference to FIGS. 1A to FIG. 2. FIG. 1A is a cross-sectional view showing a cross-sectional structure of the semiconductor device 1a of the first embodiment which is taken in a direction perpendicular to a word line thereof, FIG. 1B is a cross-sectional view showing a cross-sectional structure of the semiconductor device 1a of the first embodiment which is taken in a direction perpendicular to a bit line thereof, and FIG. 2 is an enlarged cross-sectional view showing a structure of a tunnel insulating film 11a in FIGS. 1A and 1B.

The semiconductor device 1a has a plurality of memory elements 2. To be more precise, the semiconductor device 1a has a semiconductor substrate 10, the tunnel insulating film 11a, a floating electrode film 12, an inter-poly dielectric film 13 (third insulating film), a control gate electrode 14 (gate electrode), and an element isolation insulating film 30.

Each of the memory elements 2 is formed of the tunnel insulating film 11a, the floating electrode film 12, the inter-poly dielectric film 13, and the control gate electrode 14 which are provided on the semiconductor substrate 10.

The structure of the semiconductor device 1a is as follows. First, as shown in FIG. 1A, a source region 20a and a drain region 20b are formed in an upper surface of the semiconductor substrate 10 with a channel formation region 21 interposed therebetween. The tunnel insulating film 11a is formed over the source region 20a, the drain region 20b, and the channel formation region 21 of the semiconductor substrate 10. Although silicon (Si), for example, is used for the semiconductor substrate 10, the material is not limited only to the foregoing.

As shown in FIG. 2, the tunnel insulating film 11a is formed of a first silicon oxide film 111 (first insulating film), a germanium adsorption film 112 (adsorption film), a germanium-containing film 113 (first film), and a second silicon oxide film 114 (second insulating film).

First, the first silicon oxide film 111 is provided on the channel formation region 21 of the semiconductor substrate 10. The germanium adsorption film 112 is formed on the first silicon oxide film 111. For example, a Si layer is used for the germanium adsorption film 112 and is oxidized in a step of manufacturing the semiconductor device 1a. Detail of this step is described in a manufacturing method to be described later.

The germanium-containing film 113 is formed on the germanium adsorption film 112. The germanium-containing film 113 has a surface germanium concentration of 1×10¹⁵ atoms/cm² or lower, which is a requisite for forming a substantially monomolecular layer. Moreover, the second silicon oxide film 114 is formed on the germanium-containing film 113.

The floating electrode film 12 formed of, for example, a silicon film is provided on the tunnel insulating film 11a (on the second silicon oxide film 114) having the structure described above. The inter-poly dielectric film 13 is provided on the floating electrode film 12 and the control gate electrode 14 is provided on the inter-poly dielectric film 13.

Moreover, as shown in FIG. 1B, the element isolation insulating film 30 made of a silicon oxide film or the like and having a STI (Shallow Trench Isolation) structure, is formed around regions of the semiconductor substrate 10 in which the memory elements 2 are formed when the semiconductor device 1a is viewed in a bit line direction. The STI is one of element isolation methods in the semiconductor manufacturing process. Specifically, a shallow trench is formed in the semiconductor substrate 10 and then filled with an insulating material such as a silicon oxide film to form an element isolating region. Generally, the STI has an advantage of small spread in a horizontal direction which facilitates miniaturization of elements.

In the embodiment, description is given by taking the silicon oxide film as an example of the main material of the tunnel insulating film 11a. However, the main material of the tunnel insulating film 11a is not limited to the above case and similar effects can be obtained also from high dielectric constant (high-k) films such as a silicon oxynitride film containing nitrogen, a silicon nitride film containing oxygen, a silicon nitride film, hafnia, hafnium silicate, alumina, hafnium aluminate, a lanthanum oxide film, and lanthanum aluminate.

Moreover, the floating electrode film 12 is made of polycrystalline silicon, for example. However, the material is not limited only to the foregoing.

For example, a silicon oxide film is used for the inter-poly dielectric film 13. Although the inter-poly dielectric film 13 is illustrated as a single layer in the drawings, the inter-poly dielectric film 13 is not limited to the above case and may also be realized by: an ONO (Oxide-Nitride-Oxide) film having a laminated structure of a silicon oxide film, a silicon nitride film, and a silicon oxide film; a NONON (Nitride-Oxide-Nitride-Oxide-Nitride) film in which the ONO film is interposed between nitride films; and the like. Moreover, the main material of the inter-poly dielectric film 13 may be a high dielectric constant (high-k) film such as a silicon oxynitride film containing nitrogen, a silicon nitride film containing oxygen, a silicon nitride film, hafnia, hafnium silicate, alumina, hafnium aluminate, a lanthanum oxide film, and lanthanum aluminate.

The embodiment shows the case where a polycrystalline silicon film is used for the floating electrode film 12, but this is merely an example. The semiconductor device 1a may otherwise have a MONOS (Metal-Oxide-Nitride-Oxide-Silicon) structure using a silicon nitride film. Meanwhile, metal such as TiN and TaN may be used as well.

Next, operations of the semiconductor device 1a are described. The semiconductor device 1a is used as an electrically erasable and programmable non-volatile semiconductor memory (Electrically Erasable and Programmable Read Only Memory; EEPROM) and the like. A writing operation is the case where electrons are injected into the floating electrode film 12 while an erasing operation is the case where the electrons in the floating electrode film 12 are erased.

In the writing operation, a high voltage is applied to the control gate electrode 14 and electrons are thereby made to pass from the semiconductor substrate 10 through the tunnel insulating film 11a and are injected into the floating electrode film 12 which is located therebelow while interposing the inter-poly dielectric film 13 in between. In the erasing operation, a method is used in which the electrons in the floating electrode film 12 are discharged and erased.

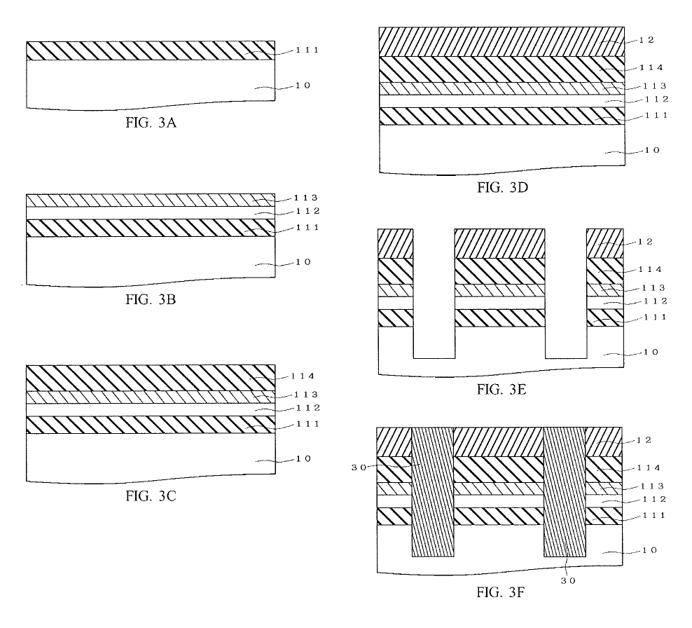

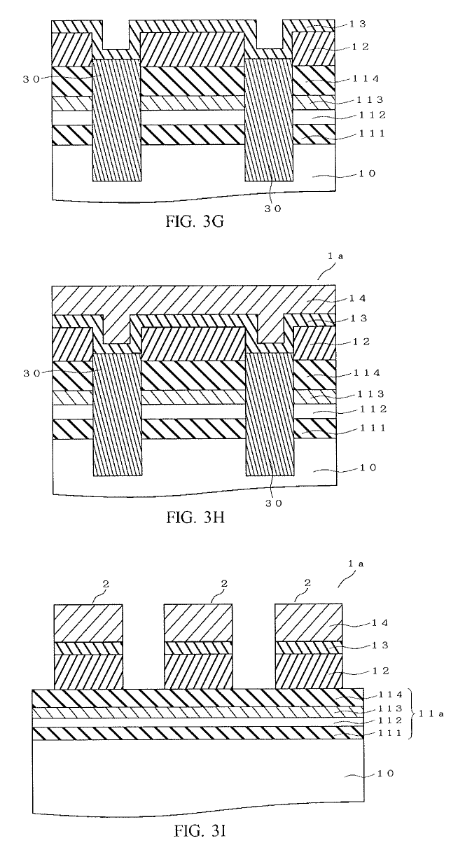

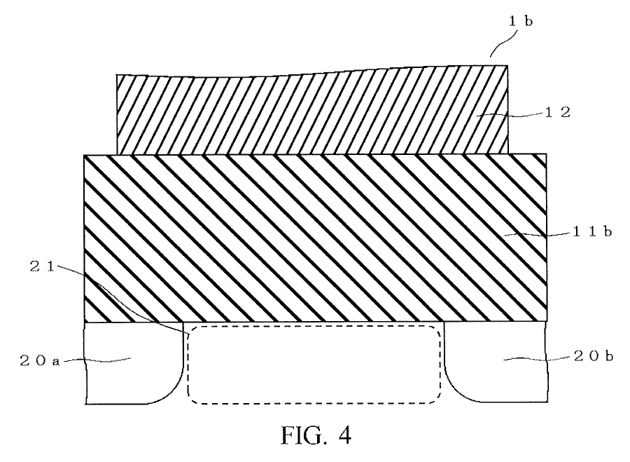

Next, a method of manufacturing the semiconductor device 1a of the first embodiment is described. FIGS. 3A to 3H are cross-sectional views showing cross sections in respective manufacturing processes of the semiconductor device 1a of the first embodiment viewed in the bit line direction. FIG. 3I is a cross-sectional view showing a cross section in a certain manufacturing process of the semiconductor device 1a of the first embodiment viewed in a word line direction.

As shown in FIG. 3A, a natural oxidation film on the surface of the semiconductor substrate 10 is wet etched with, for example, diluted hydrofluoric acid to form the tunnel insulating film 11 a on the semiconductor substrate 10. Thereafter, the first silicon oxide film 111 having a thickness of several nanometers is formed on the semiconductor substrate 10 by thermal oxidation using H₂O gas or the like as oxidation gas. Although the thermal oxidation is given as a typical film formation method for the first silicon oxide film 111, the film may be formed by chemical vapor deposition (CVD) or the like instead.

Next, the germanium adsorption film 112 is formed on the first silicon oxide film 111 by using disilane gas (Si₂H₆) or the like at predetermined reaction temperature in a reduced pressure environment. Then, as shown in FIG. 3B, the germanium-containing film 113 is formed on the germanium adsorption film 112 by using germanium hydride gas (GeH₄) or the like.

The germanium-containing film 113 is formed in such a way that the surface germanium concentration thereof is 1×10¹⁵ atoms/cm² or lower. The germanium-containing film 113 is a substantially monoatomic layer when the surface germanium concentration is 1×10¹⁵ atoms/cm² or lower. Specifically, the germanium-containing film 113 immediately after the formation thereof is a monoatomic layer film which has grown substantially uniformly on the germanium adsorption film 112. In the formation of the germanium-containing film 113, germanium first adsorbs on the germanium adsorption film 112 as germanium atoms. However, since the germanium is subjected to heat treatments including the steps to be described later, the germanium is oxidized and is transformed into a germanium oxide film. In the description of the embodiment, the germanium-containing film 113 includes both of the germanium atom film and the germanium oxide film.

As shown in FIG. 3C, the second silicon oxide film 114 is formed on the germanium-containing film 113 under a reduced pressure by using, for example, tetra(dimethylamino)silane and oxidation gas. After the formation of the second silicon oxide film 114, annealing for improving the film quality of the second silicon oxide film 114 is performed. However, this annealing may be omitted because the film quality can be improved in annealing performed in subsequent film formation steps and the like.

As shown in FIG. 3D, the floating electrode film 12 made of the polycrystalline silicon film is formed on the second silicon oxide film 114 under a reduced pressure by using, for example, silicon hydride gas (SiH₄). After the formation of the floating electrode film 12, annealing for polycrystallization of the floating electrode film 12 is performed in an inert gas. However, this annealing may be omitted because the floating electrode film 12 can be polycrystallized by annealing performed in subsequent film formation steps and the like.

After the tunnel insulating film 11a and the floating electrode film 12 are formed by performing the steps described above, etching in the word line direction is performed to form the plurality of memory elements 2. Specifically, the floating electrode film 12, the second silicon oxide film 114, the germanium-containing film 113, the germanium adsorption film 112, the first silicon oxide film 111, and part of the semiconductor substrate 10 are etched away by reactive ion etching (RIE), wet etching, or the like (FIG. 3E).

The element isolation insulating film 30 is formed in such a way as to fill the portions etched away as described above, by using, for example, polysilazane (PSZ) which is an inorganic polymer. After the formation of the element isolation insulating film 30, densification annealing or the like is performed in order to densify the element isolation insulating film 30. Then, the element isolation insulating film 30 is polished and planarized to the level of a surface of the floating electrode film 12 by chemical mechanical polishing (CMP) using an abrasive (slurry), which enhances a mechanical polishing effect and thereby obtains a smooth polished surface (FIG. 3F).

Part of the element isolation insulating film 30 between portions of the floating electrode film 12 is etched away by wet etching or the like. Then, as shown in FIG. 3G, the inter-poly dielectric film 13 is formed under a reduced pressure by using, for example, tetra(dimethylamino)silane and oxidation gas. After the formation of the inter-poly dielectric film 13, annealing for improving the film quality of the inter-poly dielectric film 13 is performed. However, this annealing may be omitted because the film quality can be improved in annealing performed in subsequent film formation steps and the like.

The control gate electrode 14 is formed on the inter-poly dielectric film 13 under a reduced pressure by using, for example, SiH₄. After the formation of the control gate electrode 14, annealing for polycrystallization of the control gate electrode 14 is performed in an inert gas.

Thereafter, the control gate electrode 14, the inter-poly dielectric film 13, and the floating electrode film 12 are processed in the bit line direction by RIE, wet etching, or the like. Eventually, there is formed the semiconductor device 1a having a structure as shown in FIG. 3H when viewed in the bit line direction and as shown in FIG. 3I when viewed in the word line direction.

Then, for example, phosphorus (P) is implanted into the semiconductor substrate 10 in a dose amount of 1×10¹⁵ cm⁻² and at incidence energy of 5 KeV with the control gate electrode 14 used as a mask and then rapid annealing is performed. The source region 20a and the drain region 20b are thereby formed. The structure shown in FIG. 1A is thus obtained.

As shown in FIG. 3G, the shape of the inter-poly dielectric film 13 is formed into square-U shapes each locating a portion of the floating electrode film 12 at the center. The surface area of the floating electrode film 12 in contact with the inter-poly dielectric film 13 can be thereby made as large as possible. When the contact area between the floating electrode film 12 and the inter-poly dielectric film 13 is large, an electric field to be applied to the inter-poly dielectric film 13 becomes small and an electric field stress on the inter-poly dielectric film 13 can be thereby relaxed. Accordingly, it is possible to suppress deterioration in an interfacial characteristic between the floating electrode film 12 and the inter-poly dielectric film 13 as well as deterioration in an insulating performance of the inter-poly dielectric film 13. The inter-poly dielectric film 13 may also be formed into a straight shape in such a manner as to be substantially parallel to the semiconductor substrate 10. In this case, the step of etching the element isolation insulating film 30 between the portions of the floating electrode film 12 as shown in FIG. 3G can be omitted.

The manufacturing method described above is merely an example. For instance, the films may be formed not only by CVD but also by methods such as atomic layer deposition (ALD) in which growth can be controlled by the atomic layer, sputtering, physical vapor deposition (PVD), coating, and spraying. Moreover, the substances mentioned above as the reactive gas and the inert gas which are used in the film formation by CVD and the like are merely examples and the substances are not limited only to the foregoing.

Moreover, when the semiconductor device 1a has a MONOS structure using a silicon nitride film for the floating electrode film 12, the floating electrode film 12 is a silicon nitride film formed by using dichlorosilane (SiCl₂H₂) as silicon gas and ammonia (NH₃) or the like as nitrogen gas.

The floating electrode and the control gate electrode may include metal films such as WN, TiN, TaN or the like. These metal films are formed by, for example, CVD or PVD.

Effects of the semiconductor device 1a of the first embodiment are described with reference to a comparative example.

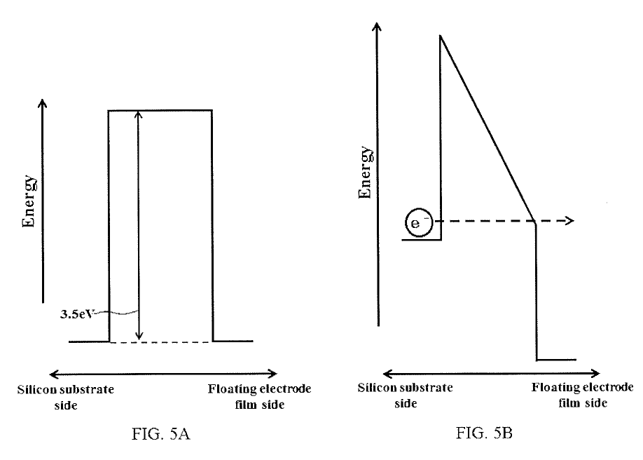

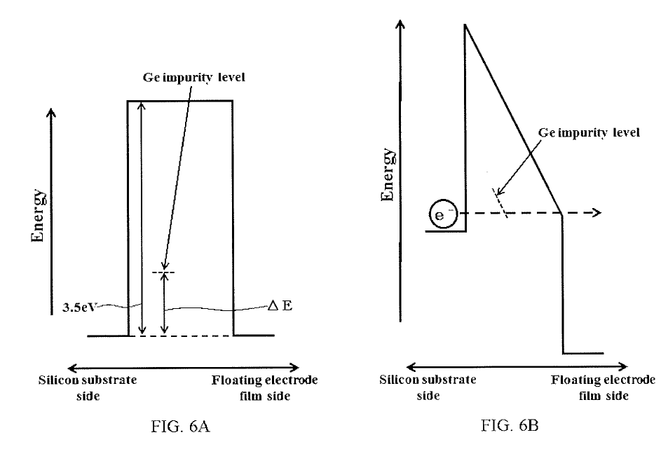

FIG. 4 is an enlarged cross-sectional view showing a structure of a tunnel insulating film 11b in a semiconductor device 1b of the comparative example, FIG. 5A is an energy band diagram of a conduction band in the tunnel insulating film 11b of the semiconductor device 1b of the comparative example, and FIG. 5B is an energy band diagram of a conduction band in the tunnel insulating film 11b of the semiconductor device 1b of the comparative example during writing operation (during injection of electrons). Moreover, FIG. 6A is an energy band diagram of a conduction band in the tunnel insulating film 11a of the semiconductor device 1a of the first embodiment and FIG. 6B is an energy band diagram of a conduction band in the tunnel insulating film 11a of the semiconductor device 1a of the first embodiment during writing operation (during injection of electrons).

The comparative example is different from the first embodiment in that the tunnel insulating film 11b neither has the germanium adsorption film 112 nor the germanium-containing film 113. Specifically, in the semiconductor device 1b, the tunnel insulating film 11b including only the silicon oxide film is formed on the channel formation region 21 of the semiconductor substrate 10. The floating electrode film 12 and the like are formed on the tunnel insulating film 11b as in the first embodiment.

The energy band diagram of the conduction band in the tunnel insulating film 11b of the semiconductor device 1b of the comparative example is as shown in FIG. 5A and indicates that the tunnel insulating film 11b is formed of the silicon oxide film having barrier energy of about 3.5 eV. Moreover, as shown in FIG. 5B, application of certain voltage to the control gate electrode 14 causes electrons to pass through the tunnel insulating film 11b from the channel formation region 21 of the semiconductor substrate 10 due to quantum tunneling and to be injected into the floating electrode film 12.

In the semiconductor device 1a of the first embodiment, the energy band diagram of the conduction band in the tunnel insulating film 11a is as shown in FIG. 6A and, in the energy barrier of the first silicon oxide film 111 and the second silicon oxide film 114, there exists a germanium impurity level which derives from the germanium-containing film 113 having the surface germanium concentration of 1×10¹⁵ atoms/cm² or lower. Moreover, as shown in FIG. 6B, application of certain voltage to the control gate electrode 14 causes electrons to pass through the tunnel insulating film 11b from the channel formation region 21 of the semiconductor substrate 10 via the germanium impurity level due to quantum tunneling and to be injected into the floating electrode film 12.

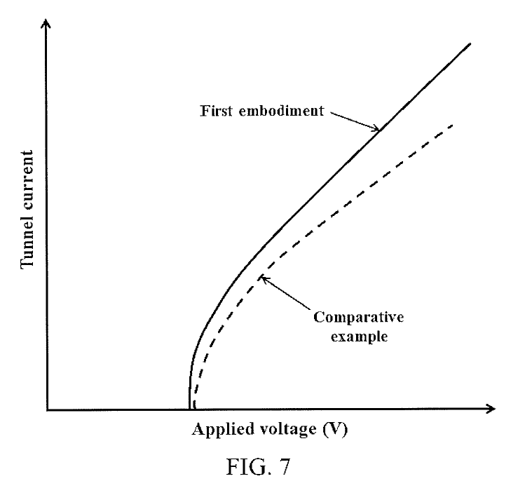

Description is given of effects of electron injection via the germanium impurity level as seen in the semiconductor device 1a of the first embodiment. FIG. 7 is a graph showing relationships between a tunnel current and an applied electric field in the first embodiment and the comparative example.

As shown in FIG. 7, due to the electron injection (electron conduction) via the germanium impurity level, the difference between the tunnel current value of the embodiment and the tunnel current value of the comparative example is small on a low electric field side while the difference between the tunnel current value of the embodiment and the tunnel current value of the comparative example is large on a high electric field side.

The above result indicates the following fact. In the low electric field (low applied voltage) side, the tunnel current of the embodiment requires almost the same applied voltage as that in the case of the comparative example. Meanwhile, in the high electric field (high applied voltage) side, the same amount of the tunnel current can be made to flow in the embodiment by application of a lower electric field (applied voltage) than that in the case of the comparative example.

The effect of the value of the tunnel current becoming larger than that of the comparative example is the effect observed on the high electric field side. Accordingly, injection of electrons into the floating electrode film 12 is suppressed on the low electric field side. Hence, variation of threshold voltage due to erroneous writing is small and the charge holding characteristic is fine on the low electric filed side. In other words, the semiconductor device 1a of the embodiment can achieve both an effect of improving the injection efficiency of electrons (effect of reducing writing voltage) on the high electric field side and an effect of maintaining a data (charge) holding characteristic on the low electric field side.

Due to the reasons described above, the electric field required to obtain the current density corresponding to writing can be reduced while maintaining the charge holding capability of the floating electrode film 12. Accordingly, the voltage (V_{pgm}) applied to the control gate electrode 14 during writing can be reduced. The reduction of the voltage V_{pgm} can suppress erroneous writing to the memory element 2 which is not selected for writing, insulation breakdown of the element isolation insulating film 30 between the memory elements 2, insulation breakdown of the inter-poly dielectric film 13, and the like. In other words, it is possible to manufacture the semiconductor device 1a with high reliability while suppressing erroneous operations and breakdown.

Moreover, the germanium-containing film 113 having the surface germanium concentration of 1×10¹⁵ atoms/cm² or lower not only has the above-described effect of improving the charge injection efficiency and but can also suppress bonding of germanium atoms (hereafter referred to as Ge—Ge bonding) which is metallic bonding. Detail of effect of suppressing the Ge—Ge bonding is described below together with effects obtained by using the germanium adsorption film 112.

Now, description is given of effects of the germanium adsorption film 112 which is used to form the germanium-containing film 113 having the surface germanium concentration of 1×10¹⁵ atoms/cm² or lower.

Generally, when a germanium (Ge) film is formed on a silicon oxide film, germanium crystals grow while preferentially causing island growth (Stranski-Krastanow mode). In the island growth, germanium atoms bond to each other while migrating (diffusing) on a surface of the silicon oxide film and form three-dimensional crystal nuclei. Then, crystals grow three-dimensionally in island shapes. In other words, when the germanium-containing film 113 is formed directly on the first silicon oxide film 111, there are portions in the germanium-containing film 113 where Ge is agglomerated into clusters.

When Ge grows into clusters as described above, regions where the above-described oxidation of Ge is insufficient are locally present therein (particularly inside the Ge clusters and the like) and bonding (metallic bonding) of Ge atoms occurs in the regions. When there is the bonding of Ge atoms, which is the metallic bonding, lateral leakage of electrons between the memory elements 2 may occur through the Ge—Ge bonding in the tunnel insulating film 11. Such lateral leakage of electrons causes erroneous writing and erroneous erasing.

When the germanium adsorption film 112 made of, for example, Si₂H₆ is formed on the first silicon oxide film 111 and then the germanium-containing film 113 is formed by using, for example, GeH₄ as in the method of manufacturing the semiconductor device 1a of the embodiment, surface migration of germanium as described above is suppressed by bonding of Si atoms and Ge atoms in Si₂H₆ and GeH₄ and the germanium-containing film 113 can be thereby formed on the first silicon oxide film 111 substantially into the shape of a layer. Moreover, since the germanium-containing film 113 is formed to have the surface germanium concentration of 1×10¹⁵ atoms/cm² or lower, occurrence of Ge—Ge boding can be further suppressed. Note that hydrogen atoms contained in Si₂H₆ and GeH₄ dissociate into water vapor by the annealing performed in the formation of film.

In FIG. 2, the germanium adsorption film 112 and the germanium-containing film 113 are illustrated to have the same thickness. However, the size relationship of the film thicknesses is particularly not limited.

Moreover, in order to further obtain the above-described effect of improving efficiency of electron injection through the germanium impurity level of the germanium-containing film 113, the germanium impurity level may be brought closer to the channel formation region 21, for example. In this case, the thickness of the first silicon oxide film 111 is set to be smaller than the thickness of the second silicon oxide film 114.

Meanwhile, in order to obtain the effect of discharging the electrons injected into the floating electrode film 12 (effect of reducing the erasing voltage), the germanium impurity level may be brought closer to the floating electrode film 12, for example. In this case, the thickness of the first silicon oxide film 111 is set to be larger than the thickness of the second silicon oxide film 114.

In the illustration of FIG. 2, only one germanium adsorption film 112 and one germanium-containing film 113 are provided. However, a plurality of germanium adsorption films 112 and a plurality of germanium-containing films 113 may be provided. Improvement in electron injection efficiency and electron discharge efficiency can be expected from provision of a plurality of germanium impurity levels.

For example, in the semiconductor device 1a of the first embodiment, another germanium adsorption film 112, another germanium-containing film 113, and another second silicon oxide film 114 are provided on the initially formed second silicon oxide film 114. In this case, the geranium impurity level is also formed near the floating electrode film 12. Accordingly, the electron discharge efficiency of the semiconductor device 1a is improved as well.

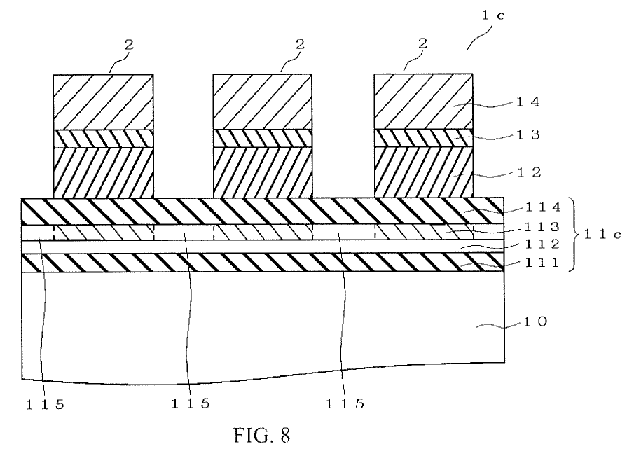

A second embodiment is described below by using FIG. 8. In the second embodiment, description of portions similar to those of the first embodiment is omitted and description is given of points which are different therefrom.

FIG. 8 is a cross-sectional view showing a cross section of a semiconductor device 1c of the second embodiment viewed in a word line direction. The second embodiment is different from the first embodiment in that a low germanium concentration region 115 (second film) having lower germanium concentration than that of a germanium-containing film 113 is provided between each two adjacent memory cells 2.

Specifically, like in the semiconductor device 1a, as shown in FIG. 1A, a semiconductor substrate 10 has a channel formation region 21 on an upper surface which is formed to be interposed between a source region 20a and a drain region 20b, and a tunnel insulating film 11c is formed on the channel formation region 21. For example, silicon (Si) is used for the semiconductor substrate 10.

Like in the semiconductor device 1a shown in FIG. 2, the tunnel insulating film 11c is formed of a first silicon oxide film 111 (first insulating film), a germanium adsorption film 112 (adsorption film), the germanium-containing film 113, and a second silicon oxide film 114 (second insulating film).

First, the first silicon oxide film 111 is provided on the channel formation region 21 of the semiconductor substrate 10. The germanium adsorption film 112 is formed on the first silicon oxide film 111.

The germanium-containing film 113 is formed on the germanium adsorption film 112. The germanium-containing film 113 has a surface germanium concentration of 1×10¹⁵ atoms/cm² or lower, which is a requisite for forming a substantially monomolecular layer. In the semiconductor device 1c of the second embodiment, as shown in FIG. 8, the low germanium concentration region 115 is provided in the germanium-containing film 113 in each portion between two adjacent memory cells 2. Moreover, the second silicon oxide film 114 is formed on the germanium-containing film 113.

A floating electrode film 12 formed of, for example, a silicon film is provided on the tunnel insulating film 11c (on the second silicon oxide film 114) having the structure described above. An inter-poly dielectric film 13 is provided on the floating electrode film 12 and a control gate electrode 14 is provided on the inter-poly dielectric film 13.

Moreover, like in the semiconductor 1a, as shown in FIG. 1B, an element isolation insulating film 30 made of a silicon oxide film or the like and having the STI structure, is formed around regions of the semiconductor substrate 10 in which the memory elements 2 are formed when the semiconductor device 1c is viewed in a bit line direction.

Also in the second embodiment, description is given by taking the silicon oxide film as an example of the main material of the tunnel insulating film 11c. However, the main material of the tunnel insulating film 11c is not limited to the above case and similar effects can be obtained also from high dielectric constant (high-k) films such as a silicon oxynitride film containing nitrogen, a silicon nitride film containing oxygen, a silicon nitride film, hafnia, hafnium silicate, alumina, hafnium aluminate, a lanthanum oxide film, and lanthanum aluminate.

Also in the second embodiment, the inter-poly dielectric film 13 is illustrated as a single layer in the drawings. However, the inter-poly dielectric film 13 is not limited to the above case and may also be realized by a film such as an ONO film having a laminated structure of a silicon oxide film, a silicon nitride film, and a silicon oxide film.

Moreover, although the embodiment shows the case in which the silicon oxide film is used for the floating electrode film 12, the semiconductor device 1c may otherwise have a MONOS structure using a silicon nitride film.

The floating electrode and the control gate electrode may include metal films such as WN, TiN, TaN or the like. These metal films are formed by, for example, CVD or PVD.

Operations of the semiconductor device 1c are the same as those of the semiconductor device 1a.

Specifically, in the writing operation, a high voltage is applied to the control gate electrode 14 and electrons are thereby made to pass from the semiconductor substrate 10 through the tunnel insulating film 11c and are injected into the floating electrode film 12 which is located therebelow while interposing the inter-poly dielectric film 13 in between. In the erasing operation, a method is used in which the electrons in the floating electrode film 12 are discharged and erased.

A method of manufacturing the semiconductor device 1c is similar to that of the semiconductor device 1a but further includes a step of providing the low germanium concentration region 115 between each two adjacent memory elements 2 as described above.

To be more specific, after the semiconductor device 1c is formed as shown in FIG. 31, anisotropic oxidation is performed by using, for example, oxygen as an oxidation gas to oxidize the germanium-containing film 113 between each two adjacent memory elements 2. The oxidation gas is not limited to oxygen. The oxidation can be performed by using oxidation gas such as H₂O and ozone and there is no particular limitation.

The anisotropic oxidation in a region between each two adjacent memory elements 2 further locally oxidizes germanium of the germanium-containing film 113 in the tunnel insulating film 11c, and the low germanium concentration region 115 can be thus formed.

Description is given of the method in which the germanium-containing film 113 between each two adjacent memory elements 2 is formed into the low germanium concentration region 115 by performing the anisotropic oxidation after the formation of the semiconductor device 1c. However, effects similar to those described below can be obtained by etching and removing the germanium-containing film 113 between each two adjacent memory elements 2 by RIE, wet etching, or the like.

The manufacturing method described above is merely an example. For instance, the films may be formed not only by CVD and ALD but also by methods such as sputtering, PVD, coating, and spraying. Moreover, the substances mentioned above as the reactive gas and the inert gas which are used in the film formation by CVD and the like are merely examples and the substances are not limited only to the foregoing.

Effects of the second embodiment are described.

In the semiconductor device 1c of the second embodiment, like the semiconductor device 1a of the first embodiment, the germanium-containing film 113 having the surface germanium concentration of 1×10¹⁵ atoms/cm² or lower is provided on the first silicon oxide film 111 by using the germanium adsorption film 112. The electron injection efficiency can be thereby increased while suppressing the lateral leakage of electrons in the region between each two adjacent memory elements 2.

Moreover, in the semiconductor device 1c of the second embodiment, the lateral leakage of electrons in the region between each two adjacent memory elements 2 can be further suppressed by performing the anisotropic oxidation of the region between each two adjacent memory elements 2 in a view in the word line direction and thereby providing the low germanium concentration region 115.

Accordingly, the voltage V_{pgm} is reduced and this can suppress erroneous writing to the memory element 2 which is not selected for writing, insulation breakdown of the element isolation insulating film 30 between the memory elements 2, insulation breakdown of the inter-poly dielectric film 13, and the like. In other words, it is possible to manufacture the semiconductor device 1c with high reliability while suppressing erroneous operations and breakdown.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method of manufacturing a semiconductor device comprising:
forming a first insulating film on a semiconductor substrate;
forming an adsorption film on the first insulating film;
forming a first film containing germanium on the adsorption film;
forming a second insulating film on the first film;
forming a floating electrode film on the second insulating film;
forming a third insulating film on the floating electrode film; and
forming a gate electrode on the third insulating film.

2. The method according to claim 1, wherein a surface germanium concentration of the first film is 1×10¹⁵ atoms/cm² or less.

3. The method according to claim 1, wherein the second insulating film is thicker than a thickness of the first insulating film.

4. The method according to claim 1, wherein the second insulating film is thinner than a thickness of the first insulating film.

5. The method according to claim 1, the method further comprising; after forming the second insulating film, a step of additionally forming the adsorption film, the first film and the second insulating film on the initially formed second insulating film.

6. The method according to claim 1, further comprising a step of performing selective etching until reaching the floating electrode film to form a plurality of memory elements and then oxidizing the first film between each adjacent two of the memory elements by using an oxidant.

7. The method according to claim 1, further comprising a step of performing selective etching to separate the first film and thereby forming a plurality of memory elements.

8. The method according to claim 1, wherein the adsorption film is formed by using disilane gas.

9. A semiconductor device comprising:
a semiconductor substrate;
a first insulating film provided on the semiconductor substrate;
a first film provided on the first insulating film having a surface germanium concentration of 1×10¹⁵ atoms/cm² or less;
a second insulating film provided on the first film;
a floating electrode film provided on the second insulating film;
a third insulating film provided on the floating electrode film; and
a gate electrode provided on the third insulating film.

10. The semiconductor device according to claim 9, further comprising an adsorption film provided between the first insulating film and the first film.

11. The semiconductor device according to claim 9, wherein the second insulating film is thicker than a thickness of the first insulating film.

12. The semiconductor device according to claim 9, wherein the second insulating film is thinner than a thickness of the first insulating film.

13. The semiconductor device according to claim 9, wherein a plurality of the first films are provided between the first insulating film and the second insulating film.

14. A semiconductor device comprising:
a plurality of the semiconductor devices according to claim 9; and
a second film containing germanium formed between the semiconductor devices, the second film having a germanium concentration lower than a germanium concentration of the first film.
